(19) United States
(12) Patent Application Publication
(10) Pub. No.: US 2012/0258858 A1
(43) Pub. Date: Oct. 11, 2012

(54) METHOD FOR DEPOSITION BY SPUTTERING, RESULTING PRODUCT, AND SPUTTERING TARGET

(75) Inventors: Nicolas Chemin, Bagneux (FR); Eric Gouardes, Toulouse (FR)

(73) Assignee: SAINT-GOBAIN GLASS FRANCE, Courbevoie (FR)

(21) Appl. No.: 13/382,954

(22) PCT Filed: Jul. 8, 2010
(86) PCT No.: PCT/EP10/59810

§ 371 Date: Jun. 25, 2012

(30) Foreign Application Priority Data
Jul. 9, 2009 (FR) 0954756

(51) Int. Cl. C23C 14/08; C04B 35/453; B01J 23/18; C23C 14/34; C23C 14/35

(52) U.S. Cl. 502/353; 204/192.1; 204/192.15; 204/298.02; 264/667

(57) ABSTRACT

The subject of the invention is a process for obtaining a substrate coated with a photocatalytic film based on a mixed oxide of bismuth and at least one metal other than bismuth, comprising at least a step of depositing said oxide by a sputtering technique.

The invention relates to the field of thin films deposited on a substrate so as to give it surface properties. The invention relates more particularly to the deposition of photocatalytic films of a mixed oxide of bismuth and another metal.

Certain particles of mixed oxides of bismuth and another metal, for example vanadium or tungsten, have photocatalysis properties, the photocatalysis being activated by radiation in the visible range or the ultraviolet range. Under the effect of radiation, electron-hole pairs are created within the material which contribute to catalysing oxidation-reduction reactions, especially leading to the degradation of organic compounds. This results in antisoiling, depolluting or bactericidal properties.

The object of the invention is to provide coatings based on such materials, especially coatings that may have a very small thickness and may retain their integrity while being resistant to mechanical or chemical attack, such as handling, abrasion, contact with pollutants or cleaning products.

For this purpose, one subject of the invention is a process for obtaining a substrate coated with a photocatalytic film based on a mixed oxide of bismuth and at least one metal other than bismuth, comprising at least a step of depositing said oxide by a sputtering technique.

Another subject of the invention is a substrate coated with a photocatalytic film based on a mixed oxide of bismuth and at least one metal other than bismuth, which can be obtained by the process according to the invention.

The substrate is preferably made of glass, and is especially a glass sheet. However, any type of material can be used, such a ceramic, metal, or polymeric organic materials. The substrate is preferably transparent or translucent. For this reason, glass or polymeric organic materials such as polycarbonate or polymethyl methacrylate are preferred. Preferably, the glass sheet has at least one dimension greater than 1 meter, or even greater than 2 or 3 meters. Its thickness is preferably between 0.5 and 19 mm, especially between 3 and 9 mm. The glass may especially be of the soda-lime-silico type, or else of the borosilicate or alumino-borosilicate type. The glass may be clear or extra-clear, or it may be tinted, for example tinted blue, bronze, gray, amber, pink, etc. The glass sheet may especially be annealed, toughened, tempered, or bent. The substrate may be flat or bent.

The mixed oxide of bismuth and another metal is preferably a defined compound, in the sense that the composition of the metal is chosen so as to allow the mixed oxide to crystallize as a uniform phase. A defined compound is a compound of perfectly defined stoichiometry, behaving as a pure substance in the sense that it melts at a constant temperature under a given pressure. These compounds are in fact most likely to exhibit high photocatalytic activity. The defined compound is preferably crystalline.

Preferably, the mixed oxide is a mixed oxide of bismuth and a single metal other than bismuth.

At least one metal other than bismuth is preferably chosen from transition metals, alkali metals and alkaline-earth metals.

The or each metal other than bismuth is especially chosen from vanadium, tungsten, niobium, tantalum, calcium, barium and sodium. Vanadium and tungsten give the best results.

The mixed oxide of bismuth and at least one metal other than bismuth is preferably chosen from BiVO₄, Bi₂WO₆, BiNbO₄, BiTaO₄, CaBi₂O₄, BaBiO₃ and NaBiO₃. These compounds, especially BiVO₄ and Bi₂WO₆, are the most effective in terms of photocatalysis activated by visible light. The mixed oxide BiVO₄ is preferably crystalline in the scheelite (monoclinic phase) form.

The thickness of the film is preferably between 1 nm and 1 micron, especially between 2 and 50 nm, or between 5 and 20 nm or between 5 and 15 nm and even between 5 and 10 nm or between 10 and 20 nm. By choosing small thicknesses it is possible to reduce the effects of reflection and absorption of the visible light.

The oxide is preferably deposited by a magnetron sputtering technique, especially DC (direct current) sputtering, pulsed DC sputtering (the polarity being periodically reversed over a time of the order of 0.1 to 10 μs at a frequency possibly ranging from 10 to 500 kHz) or RF (radiofrequency) sputtering. These techniques are the most suitable for rapid deposition on large substrates.

The deposition step may be followed by a heat treatment step, especially of the annealing, tempering or bending type. The annealing may be rapid annealing as described in application WO 2008/096089, for example using a laser, a flame annealing system or a plasma torch. This heat treatment step preferably heats the film to a temperature of at least 200° C., especially 300° C., or even above 600° C. in the case of tempering or bending. This step may improve the crystallization characteristics of the film, making it easier for crystals to grow around seeds possibly already present after the deposition.

The substrate according to the invention may be coated with a film based on a mixed oxide of bismuth and another metal on only one of its sides, or on both sides, or over only a portion of one side and/or the other side.

Apart from the film based on a mixed oxide of bismuth and another metal, the substrate according to the invention may be coated, on the same side or on the other side, with at least one other film, or even a multilayer coating.

For example, it is possible to deposit a low-E (low-emissivity) film or coating (especially comprising at least one silver film), a solar-control, antireflection, antistatic, electrically conductive or reflective film or coating (for example a silver film for a mirror), or else a coat of paint, lacquer or enamel. In particular, it is possible to deposit one or more sublayers beneath the film based on a mixed oxide of bismuth and another metal. It is possible especially to deposit films acting as a barrier to the migration of alkali metals coming from the substrate, these possibly poisoning the photocatalysis. It is also possible to deposit one or more films intended to reduce the light reflection of the film based on a mixed oxide of bismuth and another metal and/or for obtaining a neutral or slightly bluish tint in reflection. In this case, it is preferable to use interference effects by alternating films of high refractive index with films of low refractive index. It is also possible to deposit a film intended to promote the growth of the film based on a mixed oxide of bismuth and another metal depending on the desired crystalline phase.

The film based on a mixed oxide of bismuth and another metal is preferably the film furthest away from the substrate, and therefore in contact with the ambient air. In this way, it will be more suitable for interacting with the pollutants in the atmosphere and for fulfilling its depolluting or self-cleaning function.

The other films deposited on one or other side of substrate are preferably deposited by sputtering, especially magnetron sputtering.

Another subject of the invention is glazing, especially for buildings, vehicles (rear windows, side windows, sunroofs) or for furniture (for example partitions, doors, refrigerator shelves), or mirrors, or glass curtain walling, comprising at least one substrate according to the invention.

The glazing may be single or multiple glazing (for example double glazing or triple glazing), or else laminated glazing.

Yet another subject of the invention is a sputtering target comprising oxygen, bismuth and at least one metal other than bismuth. This target is intended to be used for implementing the process according to the invention. Advantageously, the target essentially consists of oxygen, bismuth and a metal other than bismuth.

Preferably, at least one metal (or the or each metal) other than bismuth is chosen from transition metals, alkali metals and alkaline-earth metals. At least one metal other than bismuth is chosen especially from vanadium, tungsten, niobium, tantalum, calcium, barium and sodium.

Several processes for obtaining the target are possible.

According to a first method of implementation, powders of at least one mixed oxide of bismuth and at least one metal other than bismuth are agglomerated. In this case, the raw material is a powder of a mixed oxide already containing bismuth and the or each metal other than bismuth. In particular, it may be a BiVO₄ or Bi₂WO₆ powder. These mixed oxide powders may be obtained by various methods, including:
precipitation of precursors, especially various salts, nitrates, chlorides, alcoholates, etc.;
hydrothermal processing;
solid-state reactions, under pressure and/or at high temperature, using the corresponding oxides.

The mixed oxide powders may then be formed by agglomeration, especially by pressing and sintering, in order to obtain the targets according to the invention. The pressing or sintering may be carried out under pressures that may range up to several hundred bar and temperatures typically between 700 and 1500° C.

According to a second method of implementation, bismuth oxide powders and powders of at least one oxide of a metal other than bismuth are agglomerated.

In this case, the process starts with oxide powders, therefore with bismuth oxide powders and powders of an oxide of another metal, for example vanadium or tungsten. The powders are formed by agglomeration, especially by pressing and sintering, in order to obtain the targets according to the invention.

According to a third method of implementation, intermediate between the first two, powders of a mixed oxide of bismuth and another metal and powders of a metal oxide may be agglomerated. For example, it is possible to form a target by agglomerating mixed bismuth vanadium oxide powders with vanadium oxide powders.

The DC or pulsed DC sputtering technique requires the use of conducting targets, or in any case those having a low resistivity. If necessary, the target may be made conducting by various means. In particular, it may be made oxygen-substoichiometric, for example by means of a heat treatment in an inert atmosphere (argon, nitrogen, etc.) or reducing atmosphere (for example a nitrogen/hydrogen mixture). Alternatively or in addition, the target may be made conducting by doping it with atoms (p-doping or n-doping), especially with aluminum, silver or copper.

The target may have the same stoichiometry as the final film, or a different stoichiometry. This second alternative makes it possible for any volatility differences during sintering and/or differences in sputtering rates between bismuth and the other metal to be more easily accommodated. In this case, it is preferable to use a target obtained by agglomerating several powders differing in nature, for example bismuth oxide powders and powders of another metal oxide, or powders of a mixed oxide of bismuth and another metal and powders of another metal oxide. Using this technique, the respective amounts of bismuth oxide and another metal oxide in the target may be easily adapted to the sputtering conditions so as to obtain in fine the desired stoichiometry in the film.

The invention will be better understood on reading an example of a nonlimiting embodiment.

Particles of the chemical formula BiVO₄ were prepared as follows. A 500 ml solution containing 0.1 mol/l bismuth was prepared by dissolving Bi(NO₃)₃·5H₂O in 0.75 mol/l nitric acid. Under magnetic stirring, 4.6 g of V₂O₅ were added to the solution so as to obtain a vanadium concentration of 0.1 mol/l in the reaction mixture. The mixture was stirred at room temperature for 72 hours before being centrifuged, washed three times with water and dried under a stream of nitrogen. The particles obtained had a scheelite monoclinic structure. The particles were prismatic and varying in size between 0.1 and 1 μm.

The particles were then used to form a sputtering target. In a first step manufacturing the target, 100 g of BiVO₄ powder were compacted under a pressure of 5 bar using a hydraulic press so as to obtain a disk 10 cm in diameter and about 1 cm in thickness. In a second step, the disk obtained was sintered by carrying out a first heat treatment in air at 900° C. for 24 hours followed by a second heat treatment at 900° C. in nitrogen for 24 hours. This treatment in nitrogen enables the resistivity of the target to be reduced.

The target thus produced was able to be used for deposition by sputtering. To do this, a base vacuum (10⁻⁷ to 10⁻⁵ mbar) was created in the deposition chamber and then a stream of argon and oxygen was injected into the chamber, regulating the pressure in the chamber to constant pressure of 1 to 10 μbar.

A clear soda-lime-silica glass substrate was placed in the chamber, and the target was polarized according to the chosen mode (DC, pulse DC or RF), thereby creating a plasma and resulting in the sputtering of the BiVO₄ target onto the substrate position facing the target.

The proportion of argon and oxygen may be chosen so as to adjust the oxygen composition of the film (the target already being depleted in oxygen so as to make it conducting and the method used in pure Ar making it possible for the amount of oxygen present in the film compared with the target to be further reduced).

After the annealing, a photocatalytic film of bismuth and vanadium oxide deposited on the glass substrate was obtained. The coated substrate may be integrated into all types of glazing.

1. A process for obtaining a substrate coated with a photocatalytic film, comprising depositing a mixed oxide of bismuth and at least one metal other than bismuth on a substrate by a sputtering technique.

2. The process of claim 1, wherein the substrate is a glass sheet.

3. The process of claim 1, wherein the mixed oxide of bismuth and at least one metal other than bismuth is a defined compound.

4. The process of claim 1, wherein the at least one metal other than bismuth is at least one selected from the group consisting of a transition metal, an alkali metal and an alkaline-earth metal.

5. The process of claim 4, wherein the at least one metal other than bismuth is at least one selected from the group consisting of vanadium, tungsten, niobium, tantalum, calcium, barium and sodium.

6. The process of claim 5, wherein the mixed oxide of bismuth and at least one metal other than bismuth is selected from the group consisting of BiVO₄, Bi₂WO₆, BiNbO₄, BiTaO₄, CaBi₂O₄, BaBiO₃ and NaBiO₃.

7. The process of claim 1, wherein the mixed oxide is deposited by a DC or RF magnetron sputtering technique.

8. The process of claim 1, further comprising a heat treatment following the depositing of the mixed oxide.

9. A substrate coated with a photocatalytic film, obtained by the process of claim 1.

10. A glazing, comprising a substrate of claim 9.

11. A sputtering target, comprising oxygen, bismuth and a metal other than bismuth.

12. The target of claim 11, wherein the metal other than bismuth is at least one selected from the group consisting of a transition metal, an alkali metal and an alkaline-earth metal.

13. The target of claim 12, wherein the metal other than bismuth is at least one selected from the group consisting of vanadium, tungsten, niobium, tantalum, calcium, barium and sodium.

14. A process for obtaining the target of claim 11, the process comprising agglomerating at least one powder of at least one mixed oxide of bismuth and at least one metal other than bismuth.

15. A process for obtaining the target of claim 11, the process comprising agglomerating at least one bismuth oxide powder and at least one powder of at least one oxide of a metal other than bismuth.

16. The process of claim 8, wherein the heat treatment involves annealing, tempering or bending.
